(19) United States
(12) Patent Application Publication
(10) Pub. No.: US 2025/0167111 A1
(43) Pub. Date: May 22, 2025

(54) SEMICONDUCTOR DEVICE AND METHOD OF FABRICATING THE SAME

(71) Applicant: Samsung Electronics Co., Ltd., Suwon-si (KR)

(72) Inventors: Jisoo OH, Suwon-si (KR); Kiil Kim, Suwon-si (KR); Changbea Park, Suwon-si (KR)

(73) Assignee: Samsung Electronics Co., Ltd., Suwon-si (KR)

(21) Appl. No.: 18/674,263

(22) Filed: May 24, 2024

(30) Foreign Application Priority Data
Nov. 22, 2023 (KR) 10-2023-0162850

(51) Int. Cl. H01L 23/528; H01L 21/768

(52) U.S. Cl. CPC H01L 23/5283; H01L 21/76816; H01L 21/76897

(57) ABSTRACT

Provided is a semiconductor device including a lower structure, a dielectric layer on the lower structure, and first and second interconnection lines extending in a first direction in the dielectric layer and alternately disposed and spaced apart from each other in a second direction, perpendicular to the first direction, at least one of the first interconnection lines includes a first subpattern and a second subpattern overlapping in the first direction and spaced apart from each other, at least one of the second interconnection lines includes a third subpattern and a fourth subpattern overlapping in the first direction and spaced apart from each other, two ends of the first subpattern and the second subpattern respectively facing each other in the first direction have a convex protruding shape, and two ends of the third subpattern and the fourth subpattern respectively facing each other in the first direction have a concave protruding shape.

### CROSS-REFERENCE TO RELATED APPLICATION

This application claims priority to Korean Patent Application No. 10-2023-0162850 filed on Nov. 22, 2023 in the Korean Intellectual Property Office, the disclosure of which is incorporated herein in its entirety by reference.

### BACKGROUND

Embodiments of the present disclosure relate to a semiconductor device and a method of fabricating the same.

As a method to implement high resolution of fine patterns in semiconductor processes, various self-aligned patterning methods such as double or quadruple patterning are being extensively developed and researched. The self-aligned patterning process may be used, for example, in an interconnection line process such as back end of line (BEOL) and a fine pattern formation process.

Due to recent demand for reduced spacing, defects may occur in a cutoff process introduced to separate lines in the self-aligned patterning process, and unwanted short circuits between interconnection lines in subsequent processes may be caused.

### SUMMARY

One or more embodiments provide a semiconductor device and a method of manufacturing the same using a self-aligned patterning process with improved reliability of a cutoff process.

According to an aspect of one or more embodiments, there is provided a semiconductor device including a lower structure, a dielectric layer on the lower structure, and first interconnection lines and second interconnection lines extending in a first direction in the dielectric layer and alternately disposed and spaced apart from each other in a second direction, perpendicular to the first direction, wherein at least one of the first interconnection lines includes a first subpattern and a second subpattern overlapping in the first direction and spaced apart from each other, wherein at least one of the second interconnection lines includes a third subpattern and a fourth subpattern overlapping in the first direction and spaced apart from each other, wherein two ends of the first subpattern and two ends of the second subpattern respectively facing each other in the first direction have a convex protruding shape, and wherein two ends of the third subpattern and two ends of the fourth subpattern respectively facing each other in the first direction have a concave protruding shape.

According to another aspect of one or more embodiments, there is provided a semiconductor device including a lower structure, a plurality of spacers extending in a first direction on the lower structure and spaced apart in a second direction perpendicular to the first direction, first subpatterns and second subpatterns, overlapping in the first direction between the plurality of spacers, on the lower structure, the first subpatterns and second subpatterns having two ends opposite to each other being spaced apart from each other and protruding convexly, third subpatterns and fourth subpatterns spaced apart from the first subpatterns and the second subpatterns in the second direction, between the plurality of spacers, on the lower structure, and overlapping in the first direction, the third subpatterns and the fourth subpatterns having two ends opposite to each other being spaced apart from each other and protruding concavely, a first cut spacer between the first subpattern and the second subpattern, a material of the first cut spacer being same as a material of the plurality of spacers, and a second cut spacer between the third subpattern and the fourth subpattern, a material of the second cut spacer being same as the material of the plurality of spacers, wherein a minimum width between the first subpattern and the second subpattern is less than a minimum width between the third subpattern and the fourth subpattern.

According to still another aspect of one or more embodiments, there is provided a method of manufacturing a semiconductor device, including forming a hard mask layer on a target layer, forming, on the hard mask layer, a plurality of mandrel lines respectively including side walls extending in a first direction and spaced apart in a second direction intersecting the first direction, based on a first mask, and each of the plurality of mandrel lines including a first cut spacer region disconnected in the first direction and a second cut spacer region divided by enlarged portions having a width increasing in the first direction, forming a first cut spacer in the first cut spacer region and forming a second cut spacer between the enlarged portions of the second cut spacer region by conformally forming a spacer material layer on the plurality of mandrel lines and filling the first cut spacer region and the second cut spacer region, forming sidewall spacers on the sidewalls of the plurality of mandrel lines respectively by etching back the spacer material layer, removing the plurality of mandrel lines from the sidewall spacers and the enlarged portions based on a second mask, forming a mask pattern by etching the hard mask layer using the first cut spacer and the second cut spacer along with the sidewall spacers, forming a plurality of trenches by etching the target layer based on the mask patter, and forming a plurality of interconnection lines by filling the plurality of trenches with a conductive material.

### BRIEF DESCRIPTION OF DRAWINGS

The above and other aspects, features, and advantages of the embodiments will be more clearly understood from the following detailed description, taken in conjunction with the accompanying drawings, in which:

FIG. 1 is a top view of a semiconductor device according to one or more embodiments;

FIGS. 2A and 2B are partially enlarged views of the semiconductor device of FIG. 1;

FIGS. 3A, 3B, and 3C are cross-sectional views of the semiconductor device of FIG. 1;

FIGS. 4 and 5 are top plan views of a semiconductor device according to one or more embodiments;

FIG. 6 is a flowchart illustrating a method of manufacturing a semiconductor device according to one or more embodiments;

FIGS. 7A, 8A, and 9A are top plan views illustrating processes (mandrel line formation) of a method of manufacturing a semiconductor device according to one or more embodiments;

FIGS. 7B, 8B, and 9B are cross-sectional views taken along line I1-I1′ of the plane of FIGS. 7A, 8A, and 9A, respectively;

FIGS. 7C, 8C, and 9C are cross-sectional views taken along line I2-I2′ of the plane of FIGS. 7A, 8A, and 9A, respectively;

FIG. 10A is a top plan view illustrating a partial process (cut spacer formation) of a method of manufacturing a semiconductor device according to one or more embodiments;

FIG. 10B is a cross-sectional view taken along line I1-I1′ of the plane of FIG. 10A, FIG. 10C is a cross-sectional view taken along line I2-I2′ of the plane of FIG. 10A, and FIG. 10D is a cross-sectional view taken along line II-II′ of the plane of FIG. 10A;

FIGS. 11A, 12A, 13A, 14A, and 15A are top plan views illustrating processes (sidewall spacer formation and mask pattern formation) of a method of manufacturing a semiconductor device according to one or more embodiments;

FIGS. 11B, 12B, 13B, 14B, and 15B are cross-sectional views taken along line I1-I1′ of the plane of FIGS. 11A, 12A, 13A, 14A, and 15A, respectively, FIGS. 11C to 14C are cross-sectional views taken along line I2-I2′ of the plane of FIGS. 11A, 12A, 13A, 14A, and 15A, respectively, and FIG. 11D is a cross-sectional view taken along line II-II′ of FIG. 11A;

FIGS. 16A and 17A are top plan views illustrating a partial process (target layer etching) of a method of manufacturing a semiconductor device according to one or more embodiments, respectively;

FIGS. 16B and 17B are cross-sectional views taken along line I1-I1′ of the planes of FIGS. 16A and 17A, respectively, and FIGS. 16C and 17C are cross-sectional views taken along line I2-I2′ of the planes of FIGS. 16A and 17A, respectively; and

FIGS. 18A and 18B are cross-sectional views illustrating a partial process (interconnection formation) of a method of manufacturing a semiconductor device according to one or more embodiments.

### DETAILED DESCRIPTION

Hereinafter, various embodiments will be described in detail with reference to the attached drawings. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

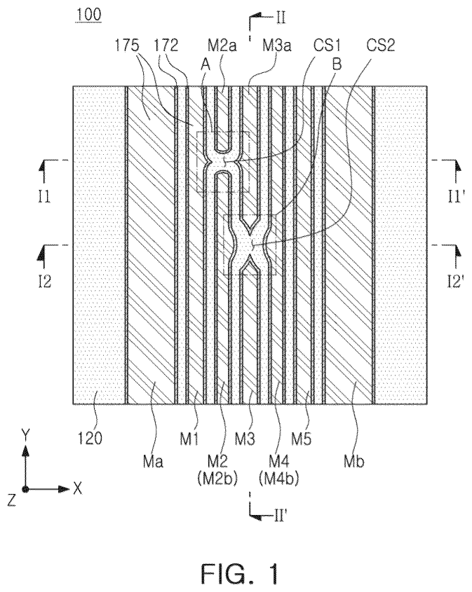

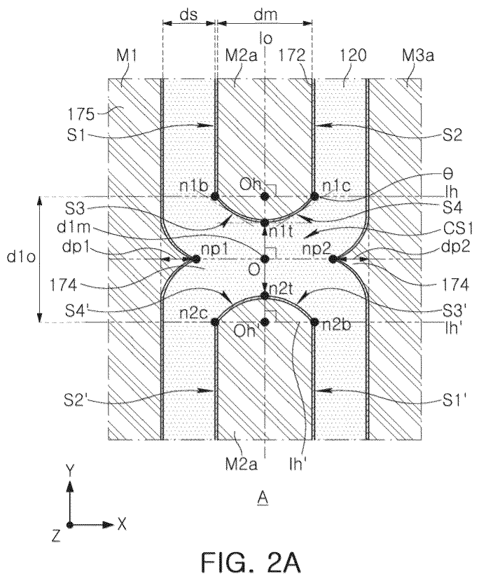

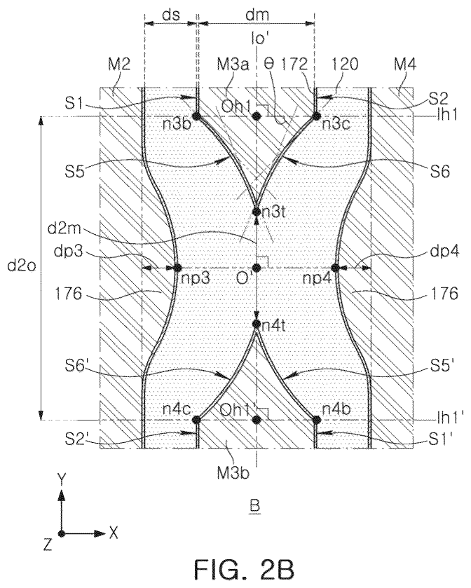

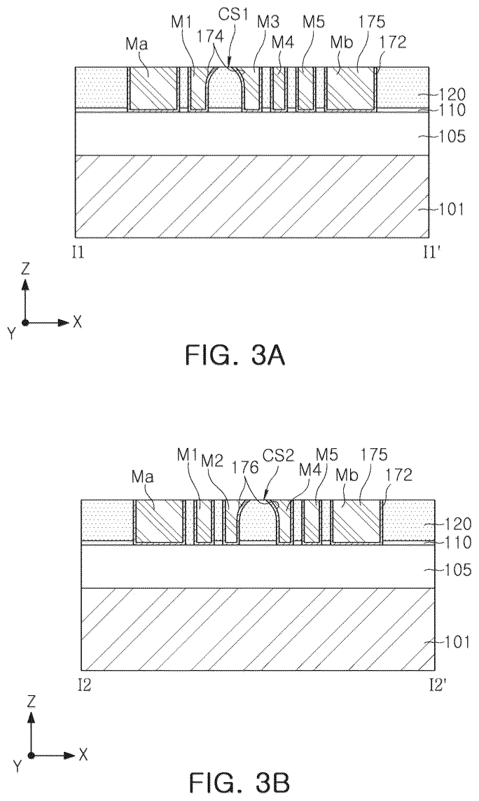

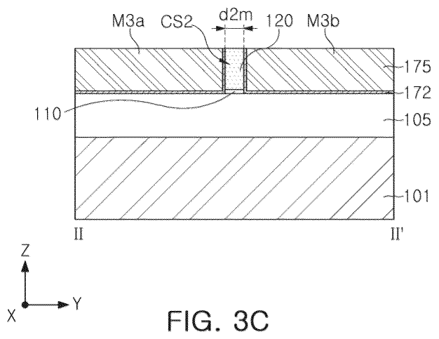

FIG. 1 is a top plan view of a semiconductor device according to one or more embodiments, FIGS. 2A and 2B are partially enlarged views of the semiconductor device of FIG. 1, and FIGS. 3A to 3C are cross-sectional views of the semiconductor device of FIG. 1.

FIG. 2A is an enlarged view of area A in the top view of the semiconductor device according to one or more embodiments in FIG. 1, and FIG. 2B is an enlarged view of area B.

FIG. 3A is a cross-sectional view taken along line I1-I1′ in the plane of FIG. 1, FIG. 3B is a cross-sectional view taken along line I2-I2′ of the plane of FIG. 1, and FIG. 3C is a cross-sectional view taken along line II-II′ of FIG. 1.

The semiconductor device 100 according to one or more embodiments may include a substrate structure 101, an interlayer insulating layer 105 on the substrate structure 101, a dielectric layer 120 on the interlayer insulating layer 105, and interconnection lines penetrating the dielectric layer 120. Embodiments are directed to a photo-lithography process and an etching process for forming a fine pattern of the semiconductor device 100, and may provide a semiconductor device 100 in which the minimum number of masks is applied to significantly reduce the number of photolithography processes and etching processes.

The substrate structure 101 may be a semiconductor substrate or a multilayer substrate such as silicon on insulator (SOI). The semiconductor substrate may include, for example, silicon (Si), germanium (Ge), silicon germanium (SiGe), silicon carbide (SiC), gallium nitride (GaN), or gallium arsenide (GaAs). The substrate structure 101 is a semiconductor substrate doped with impurities to be P-type or N-type, and may include an active region where devices such as transistors are formed.

The interlayer insulating layer 105 may be disposed on the surface of the substrate structure 101 where the active region is formed. The interlayer insulating layer 105 may include a low dielectric constant material such as silicon oxide. For example, low dielectric constant materials include flowable oxide (FOX), tonen silazen (TOSZ), undoped silica glass (USG), borosilica glass (BSG), phosphosilaca glass (PSG), borophosphosilica glass (BPSG), and plasma enhanced tetra ethyl ortho silicate (PETEOS), fluoride silicate glass (FSG), high density plasma (HDP) oxide, plasma enhanced oxide (PEOX), flowable CVD (FCVD) oxide, or combinations thereof.

The dielectric layer 120 may be provided as an area for forming an interconnection line such as BEOL, and the dielectric layer 120 may be formed on the interlayer insulating layer 105 with the etch stop film 110 interposed therebetween. The interconnection line on the dielectric layer 120 may be electrically connected to the active region through a contact structure located within the interlayer insulating layer 105. The dielectric layer 120 may include tetraethyl ortho silicate (TEOS), silicon oxide (SiO₂), silicon oxynitride (SiON), nanoporous silica, hydrogensilsesquioxanes (HSQ), polytetrafluorethylene (Teflon-AF or PTFE), silicon oxyfluoride (FSG), carbon-doped SiO₂ (SiCO), hydrogenated silicon oxycarbide (SiCOH), or low-k or ultra-low-k (ULK) (for example, dielectric constant less than or equal to 25) dielectric materials.

According to one or more embodiments, the semiconductor device 100 may include a fine pattern in which interconnection lines of different shapes are alternately arranged.

As an example, a first interconnection line M1, a second interconnection line M2, a third interconnection line M3, a fourth interconnection line M4, and a fifth interconnection line M5 and two peripheral interconnection lines Ma and Mb may be formed in the dielectric layer 120. The second interconnection line M2 is separated into two interconnection lines (M2a and M2b) by the first cut spacer CS1, and similarly, the third interconnection line M3 may be separated into two interconnection lines M3a and M3b by the second cut spacer CS2. The first and second cut spacers CS1 and CS2 may be provided in a form that may form a structure in which a portion of the dielectric layer 120 remains between the interconnection lines M2 and M3 and short-circuits the continuous interconnection lines M2 and M3.

The first to fifth interconnection lines M1, M2, M3, M4 and M5 may be patterns provided by different components.

The second and fourth interconnection lines M2 and M4 may be referred to as “mandrel interconnection lines” corresponding to an area defined (or formed) by a mandrel line. In addition, the first, third and fifth interconnection lines M1, M3 and M5 may be referred to as a “non-mandrel interconnection line” defined by sidewall spacers in the non-mandrel area (NM). All interconnection lines M1, M2, M3, M4 and M5 may have the same spacing defined by the width of the sidewall spacer, and the mandrel interconnection line and the non-mandrel interconnection line may be designed to have the same width, but embodiments are not limited thereto, and may have a different width. Two peripheral interconnection lines Ma and Mb may be disposed on both sides of the first to fifth interconnection lines M1, M2, M3, M4, and M5, respectively, and may have a larger width than the first to fifth interconnection lines M1, M2, M3, M4, and M5, but embodiments are not limited thereto.

The first to fifth interconnection lines M1, M2, M3, M4, and M5 may have different shapes.

The first type interconnection line may extend in the Y-direction, such as the first, fourth, and fifth interconnection lines M1, M4, and M5, be spaced apart from neighboring interconnection lines M2 and M3 in the X-direction, and have a shape that is not interrupted and extends continuously.

The second type interconnection line, such as the second interconnection line M2, may extend in the Y-direction and may be spaced apart from neighboring interconnection lines M1 and M3 in the X-direction, and may have a form that overlaps in the Y-direction and is separated into two sub-lines M2a and M2b that are intermittent with each other.

The third type interconnection line, such as the third interconnection line M3, may extend in the Y-direction and may be spaced apart from neighboring interconnection lines M2 and M4 in the X-direction, and may be separated into two sub-lines M3a and M3b interrupted in the Y-direction.

In this case, the second and third type interconnection lines may have different shapes at both ends of the two interrupted sub-lines M2a, M2b, M3a and M3b facing each other.

For example, both ends of the two interrupted sub-lines M2a and M2b of the second type interconnection line may have a shape protruding convexly toward each other, and both ends of the two interrupted sub-lines M3a and M3b of the third type interconnection line may have a shape protruding concavely toward each other.

The space between the two separated sub lines M2a and M2b forming the second interconnection line M2 may be separated by a first cut spacer CS1, the space between the two separated sub lines M3a and M3b forming the third interconnection line M3 may be separated by a second cut spacer CS2, and the shapes of the first cut spacer CS1 and the second cut spacer CS2 may be different from each other.

The dielectric layer 120 may extend along the Y-axis and be disposed as a spacer, between the first to fifth interconnection lines M1, M2, M3, M4, and M5. The widths (ds) of the spacers may be equal or substantially equal to each other, but is not limited to physically matching.

The spacers may physically and electrically separate the interconnection lines M1, M2, M3, M4 and M5 spaced apart along the X-axis.

According to one or more embodiments, interrupted second and third type interconnection lines, for example, the second and third interconnection lines M2 and M3, may be formed to have different shapes. In this case, the second and third type interconnection lines (hereinafter referred to as M2 and M3, respectively) may be formed to include both single lines and enlarged portions using a minimum photo mask. To this end, when the second and third type interconnection lines M2 and M3 have disconnection areas of different shapes and when the interconnection line is mandrel interconnection lines M2 and M4, an end of the second type interconnection line M2 having a convex protruding shape may be provided, and when the interconnection line is provided as non-mandrel interconnection lines M1, M3 and M5, an end of the third type interconnection line M3 having a concave protruding shape may be provided.

By reflecting the disconnected areas in the case of mandrel interconnection lines and non-mandrel interconnection lines on the photo mask, a mandrel line may be formed. The entire interconnection line may be formed using a minimized photo mask.

In the second type interconnection line, two sub-lines M2a and M2b disconnected in the Y-direction, for example, the first sub-line M2a and the second sub-line M2b, may protrude convexly toward each other in the Y-direction.

For example, referring to FIG. 2A, each of the disconnected first sub-line M2a and second sub-line M2b may have four side surfaces S1, S2, S3, and S4 on a plane.

The first sub-line M2a has an end convex downward in the Y-direction, and the first side surface S1 and the second side surface S2 extend along the Y-direction and may be arranged parallel to the Y-direction. The separation distance between the first side surface S1 and the second side surface S2 may be defined as the first width dm of the second interconnection line M2.

The first side surface S1 and the second side surface S2 may be arranged in parallel with a separation distance of the first width dm and may extend along the conductive barrier 172.

The third side surface S3 may have a curved surface extending from the first side surface S1 to the outermost point n1t of the end, and the third side surface S3 may have an outwardly convex curved surface from the first intersection point n1b with the first side surface S1 to the outermost point n1t. For example, when defining a virtual line passing through the center of the first width dm of the interconnection line M2 as the center line 1o, as any point on the third side surface S3 moves from the first intersection point n1b to the outermost point n1t, the distance from the center line 1o may decrease. For example, the third side surface S3 may have a curved surface in which the magnitude of the slope θ of the tangent line decreases from the first intersection point n1b to the outermost point n1t.

The fourth side surface S4 has a curved surface extending from the second side surface S2 to the outermost point n1t of the interconnection line M2, and the fourth side surface S4 may have an outwardly convex curved surface from the second intersection point n1c with the second side surface S2 to the outermost point n1t. For example, when defining a virtual line passing through the center of the first width dm of the interconnection line M2 as the center line 1o, as any point on the fourth side surface S4 moves from the second intersection point n1c to the outermost point n1t, the distance from the center line 1o may decrease. For example, the fourth side surface S4 may have a curved surface in which the magnitude of the slope θ of the tangent line decreases from the second intersection point n1c to the outermost point n1t.

At this time, the virtual line 1h connecting the first intersection point n1b and the second intersection point n1c meets perpendicularly to the center line 1o, and when defining the intersection point as the first midpoint Oh, among the distances from the first midpoint Oh to some points on the third side surface S3 and fourth side surface S4, the distance to the outermost point n1t may be the shortest, and the third side surface S3 and the fourth side surface S4 from the first intersection point n1b to the second intersection point n1c may have a hemi-oval shape.

The second sub-line M2b has an end that is convex upward in the Y-direction, and may have four side surfaces S1′, S2′, S3′, and S4′ similar to the first sub-line M2a.

The first side surface S1′ and the second side surface S2′ extend in the Y-direction and may be arranged parallel to the Y-direction. The separation distance between the first side surface S1′ and the second side surface S2′ may be defined as the first width dm of the second interconnection line M2.

The first side surface S1′ and the second side surface S2′ may be arranged in parallel with a separation distance of the first width dm, and may extend along the conductive barrier 172.

The third side surface S3′ has a curved surface extending from the first side surface S1′ to the outermost point n2t of the end, and the third side surface S3′ may have a curved surface that is convex outward from the first intersection point n2b with the first side surface S1′ to the outermost point n2t. For example, when defining a virtual line passing through the center of the first width dm of the interconnection line M2 as the center line 1o, in the case of any point on the third side surface S3′, the distance from the center line 1o may decrease as it moves from the first intersection point n2b to the outermost point n2t. For example, the third side surface S3′ may have a curved surface in which the magnitude of the slope θ of the tangent line decreases from the first intersection point n2b to the outermost point n2t.

The fourth side surface S4′ has a curved surface extending from the second side surface S2′ to the most origin n2t of the interconnection line M2, and the fourth side surface S4′ is connected to the second side surface S2′, and may have an outwardly convex curved surface from the second intersection point n2c to the outermost point n2t. For example, when defining a virtual line passing through the center of the first width dm of the interconnection line M2 as the center line 1o, in the case of any point on the fourth side surface S4′, the distance from the center line 1o may decrease as it moves from the second intersection point n2c to the outermost point n2t. For example, the fourth side surface S4′ may have a curved surface in which the slope of the tangent line decreases from the second intersection point n2c to the outermost point n2t.

At this time, when the virtual line 1h′ connecting the first intersection point n2b and the second intersection point n2c meets perpendicularly to the center line 1o, and when defining the intersection point as the first midpoint Oh′, a shape in which the distance to the outermost point n2t is the shortest among the distances from the first midpoint Oh′ to arbitrary points on the third side surface S3′ and the fourth side surface S4′ may be provided, and the third side surface S3′ and the fourth side surface S4′ from the first intersection point n2b to the second intersection point n2c may have a hemi-oval shape.

In this manner, the separation distance (d1o-d1m) between the first sub-line M2a and the second sub-line M2b is gradually reduced from the distance (d2o) between the first intersection point n1b and the second intersection point n2c gradually decreases to the outermost point (n1t, n2t), and may thus have the shortest separation distance dim between the outermost points (n1t, n2t). Therefore, the shortest separation distance dim may be defined as the distance between the outermost points nit of the first sub-line M2a and the outermost points n2t of the second sub-line M2b.

When the center lines 1o of the first sub-line M2a and the second sub-line M2b are coaxial, the shortest separation distance dim may be parallel to the Y-direction.

When the center lines 1o of the first sub-line M2a and the second sub-line M2b are not coaxial, the shortest separation distance dim may have a slope in the Y-direction, but embodiments are not limited thereto.

The interconnection width dm of the first sub-line M2a may be equal to a width of the second sub-line M2b, and the shortest separation distance dim of the second type interconnection line may satisfy the relationship between the first width dm of the interconnection line M2 and the following Equation 1.

$$d 1 m = dm * a \qquad [ Equation 1 ]$$

In Equation 1, a may be 1.4 to 1.8, preferably, 1.5.

The width ds of the spacers 120 on both sides of the second type interconnection line M2 may satisfy the relationship of Equation 2 below with respect to the shortest separation distance d1m.

$$d 1 m < 2 * ds \qquad [ Equation 2 ]$$

In this case, the interconnection lines M1 and M3 on both sides of the first cut spacer CS1 may further include protrusions 174 toward the first cut spacer CS1.

The protrusions 174 protrude toward the center (o) of the shortest separation distance d1m, and may include mountains (np1, np2) facing the center (o) to have a maximum protrusion length (dp1, dp2) from the side of each interconnection line (M1, M3). The mountains (np1, np2) on both sides may be arranged on a straight line, and the straight line may pass through the center (o), but embodiments are not limited thereto.

The protrusion 174 is not formed to have the same thickness as the overall thickness of the interconnection lines M1 and M3, and as illustrated in FIG. 3A, the interconnection lines M1 and M3 may be formed to extend from the top and cover the dielectric layer 120 below. Accordingly, the thickness decreases toward the mountains (np1, np2), so that the top surface may be coplanar with the dielectric layer 120.

On the other hand, in the third type interconnection line (for example, the third interconnection line M3), two interconnection lines M3a and M3b disconnected in the Y-direction, for example, the third sub-line M3a and the fourth sub-line M3b, protrude concavely in the Y-direction toward each other to form edge points n3t and n4t.

In detail, referring to FIG. 2B, each of the disconnected third sub-lines M3a and fourth sub-lines M3b may have four side surfaces S1, S2, S5, and S6 on a plane.

The third sub-line M3a has an end concavely protruding downward in the Y-direction, and the first side surface S1 and the second side surface S2 extend in the Y-direction and may be arranged parallel to the Y-direction. The separation distance between the first side surface S1 and the second side surface S2 may be defined as the first width dm of the interconnection line.

The first side surface S1 and the second side surface S2 may be arranged in parallel with a separation distance of the first width dm and may extend along the conductive barrier 172.

The third side surface S5 has a curved surface extending from the first side surface S1 to the outermost point n3t, which is the edge point of the third sub-line M3a, and the third side surface S5 may have an inwardly concave curved surface from the first intersection point n3b with the first side surface S1 to the outermost point n3t. For example, when defining the virtual line passing through the center of the first width dm of the interconnection line as the center line 1o′, as any point on the third side surface S5 moves from the first intersection point n3b to the outermost point n3t, the distance from the center line 1o′ may increase. For example, the third side surface S5 may have a curved surface where the slope of the tangent line increases from the first intersection point n3b to the outermost point n3t.

The fourth side surface S6 has a curved surface extending from the second side surface S2 to the outermost point n3t of the third sub-line M3a, and the fourth side surface S6 may have a concave curved surface from the second intersection point n3c with the second side surface S2 to the outermost point n3t. For example, when defining a virtual line passing through the center of the first width dm of the third sub-line M3a as the center line 1o′, as any point on the fourth side surface S6 moves from the second intersection point n3c to the outermost point n3t, the distance from the center line 1o′ may increase. For example, the fourth side surface S6 may have a curved surface whose slope increases from the second intersection point n3c to the outermost point n3t.

At this time, the virtual line 1h1 connecting the first intersection point n3b and the second intersection point n3c meets perpendicularly to the center line 1o′, and when forming the intersection point as the first midpoint Oh1, the distance to the outermost point n3t among the distances between any point on the third side surface S5 and the fourth side surface S6 and the first midpoint Oh1 may have the longest shape, and the third side surface S5 and the fourth side surface S6 from the first intersection point n3b to the second intersection point n3c may each have the shape of a quadrant oval with the center line 1o′ as the axis of symmetry.

The fourth sub-line M3b has an end protruding upwardly in the Y-direction and, similar to the third sub-line, may have four side surfaces S1′, S2′, S5′, and S6′.

The fourth sub-line M3b has an end protruding concavely upwardly in the Y-direction, and the first side surface S1′ and the second side surface S2′ extend in the Y-direction and may be arranged parallel to the Y-direction. The separation distance between the first side surface S1 and the second side surface S2 may be defined as the first width dm of the interconnection line.

The first side surface S1′ and the second side surface S2′ may be arranged in parallel with a separation distance of the first width dm and may extend along the conductive barrier 172.

The third side surface S5′ has a curved surface extending from the first side surface S1′ to the outermost point n4t, which is the edge point of the fourth sub-line M3b, and the third side surface S5′ may have an inwardly concave curved surface from the first intersection point n4b with the first side surface S1′ to the outermost point n4t. For example, when defining a virtual line passing through the center of the first width dm of the fourth sub-line M3b as the center line 1o′, as any point on the third side surface S5′ moves from the first intersection point n4b to the outermost point n4t, the distance from the center line 1o′ may increase. For example, the third side surface S5′ may have a curved surface in which the slope of the tangent line increases from the first intersection point n4b to the outermost point n4t.

The fourth side surface S6′ has a curved surface extending from the second side surface S2′ to the outermost point n4t of the fourth sub-line M3b, and the fourth side surface S6′ may have a concave curved surface from the second intersection point n4c with the second side surface S2′ to the outermost point n4t. For example, when defining a virtual line passing through the center of the first width dm of the fourth sub-line M3b as the center line 1o′, as any point on the fourth side surface S6′ moves from the second intersection point n4c to the outermost point n4t, the distance from the center line 1o′ may increase. For example, the fourth side surface S6′ may have a curved surface whose slope increases from the second intersection point n4c to the outermost point n4t.

The virtual line 1h1′ connecting the first intersection point n4b and the second intersection point n4c may intersect perpendicularly to the center line 1o′, and when defining the intersection point as the first midpoint Oh1′, among the distances between any point on the third side surface S5′ and the fourth side surface S6′ and the first midpoint Oh1′, the distance to the outermost point n4t may be the longest, and the third side surface S5′ and the fourth side surface S6′ from the first intersection point n4b to the second intersection point n4c may each have the shape of a quadrant oval with the center line 1o′ as the axis of symmetry.

The shortest separation distance between the third sub line M3a and the fourth sub line M3b may be defined as the distance between the outermost point n3c of the third sub-line M3a and the outermost point n4c of the fourth sub-line M3b.

When the center lines 1o′ of the third sub-line M3a and the fourth sub-line M3b are coaxial, the shortest separation distance d2m may be parallel to the Y-direction.

When the center lines 1o′ of the third sub-line M3a and the fourth sub-line M3b are not coaxial, the shortest separation distance d2m may have a slope with respect to the Y-direction, but embodiments are not limited thereto.

The shortest separation distance d2m of the third type interconnection line may satisfy the relationship between the first width dm of the interconnection line M3 and the following Equation 3.

$$d 2 m = dm * b \qquad [ Equation 3 ]$$

In Equation 3, b may be 2.8 to 3.6, preferably, 3.

The relationship between the shortest separation distance d2m of the third type interconnection line M3 and the shortest separation distance dim of the second type interconnection line M2 may satisfy the relationship in Equation 4 below.

$$d 2 m = c * d 1 m \qquad [ Equation 4 ]$$

In Equation 4, c may satisfy 1.5 to 2.2, preferably, 2.

The second cut spacer CS2 may separate the two sub lines M3a and M3b by extending the spacers 120 on both sides to have a curvature along each side and contacting each other.

At this time, the contact length of the spacers 120 on both sides may be equal to the maximum separation distance d2m, and accordingly, the two ovals may have a form that partially overlaps.

The interconnection lines M2 and M4 on both sides of the second cut spacer CS2 may further include a second protrusion 176 toward the second cut spacer CS2.

The second protrusion 176 protrudes toward the center of the shortest separation distance d2m, and may include mountains np3 and np4 facing the center O′ to have the shortest protrusion length d2m from the sides of the interconnection lines (M2, M4). The mountains np3 and np4 on both sides may be arranged on a straight line, and the straight line may pass through the center O′, but embodiments are not limited thereto.

Each shape of the second protrusion 176 may have a half-oval shape following the shape of the second cut spacer CS2, but embodiments are not limited thereto.

The second protrusion 176 does not have the same thickness as the entire thickness of the interconnection line 175, and as illustrated in FIG. 3B, may be limited to the upper portion and may be formed to cover the lower portion with the dielectric layer 120. Therefore, the thickness decreases toward the mountains np3 and np4, and the top surface may be coplanar with the dielectric layer 120.

The first cut spacer CS1 and the second cut spacer CS2 of the second and third type interconnection lines M2 and M3 interconnected with each other may be formed only of the dielectric layer 120, and may not contain any other material layers or have a separation distance such that there is a hollow space inside. For example, the first and second cut spacers CS1 and CS2 may be defined as areas filled with the dielectric layer 120.

The intermittent interconnection lines M2 and M3 are implemented to have different shapes depending on the mandrel lines and non-mandrel lines, and to this end, the interrupted shape is reflected in the photo mask, thereby significantly reducing the number of photo masks, simplifying the process, and implementing self-aligned interconnection lines.

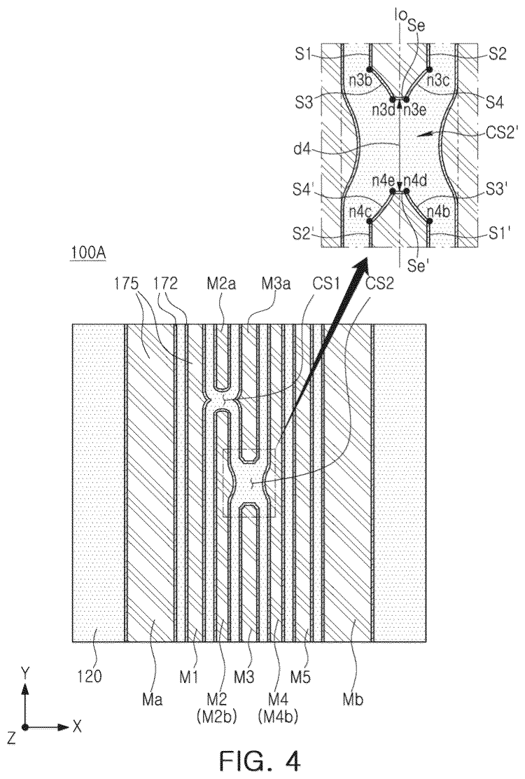

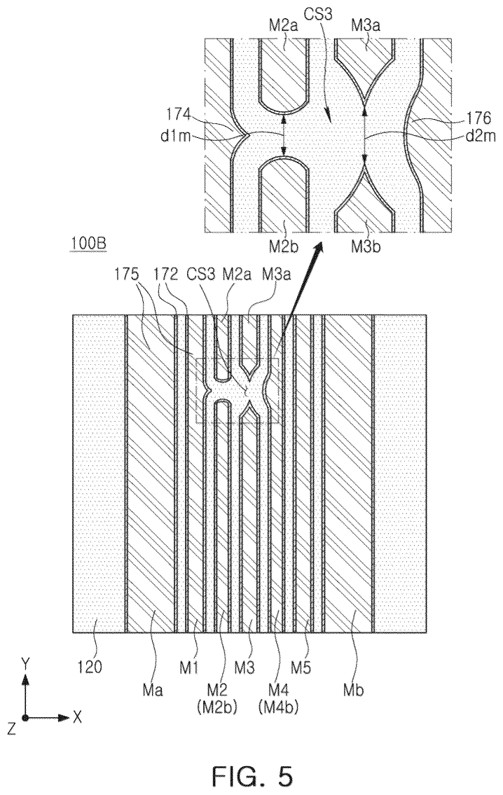

FIGS. 4 and 5 are top views of a semiconductor device according to one or more embodiments.

Referring to FIG. 4, a semiconductor device 100A according to one or more embodiments has substantially the same shape as the semiconductor device 100 of FIGS. 1 to 3C. In the semiconductor device 100A of FIG. 4, the second type interconnection line M2 has the same shape, but the third type interconnection line M3 is partially different.

For example, the third type interconnection line M3 may include the fifth side surfaces Se and Se′ without edge points of the third sub-line M3a and the fourth sub-line M3b, respectively.

The fifth side surfaces Se and Se′ are sides connecting the third side surface S3 and the fourth side surface S4, and contact points n3d, n3e, n4d and n4e with each side at both ends may be disposed to be parallel to the virtual line extending the first intersection point n3b and the second intersection point n3c.

The fifth side surfaces Se and Se′ may be formed without the outermost point, which is the edge point, and the shortest separation distance d4 may be defined by parallel planes facing each other without the outermost point.

In addition, in FIG. 4, it is illustrated as including a third side surface S3 and a fourth side surface S4, and may also be implemented as a quadrangular shape with only the first side surface S1, second side surface S2, and fifth side surface Se.

The relationship between the shortest separation distance d4 and the first width dm of the interconnection may satisfy the relationship in Equation 3 (d2m is replaced by d4).

In this case, when the edge point is not formed, the risk of a short circuit occurring due to charges converging on the edge point and penetrating the dielectric layer 120 may be reduced, thereby improving electrical reliability.

Referring to FIG. 5, a semiconductor device 100B according to one or more embodiments has substantially the same shape as the semiconductor device 100 of FIGS. 1 to 3C. In the semiconductor device 100B of FIG. 5, both the second type interconnection line M2 and the third type interconnection line M3 have the same shape. A first cut spacer CS1 and a second cut spacer CS2 may be formed side by side in the X-direction, and the first cut spacer CS1 and the second cut spacer CS2 may extend to form a common cut spacer CS3.

For example, the common cut spacer CS3 may be formed by applying to a mask pattern so that the first cut spacer CS1 and the second cut spacer CS2 are formed side by side, and accordingly, the first protrusion 174 is formed only on one side of the common cut spacer CS3, and the second protrusion 176 is formed only on the other side of the common cut spacer CS3. Therefore, the two protrusions 174 and 176 that protrude from the common cut spacer CS3 may have different shapes.

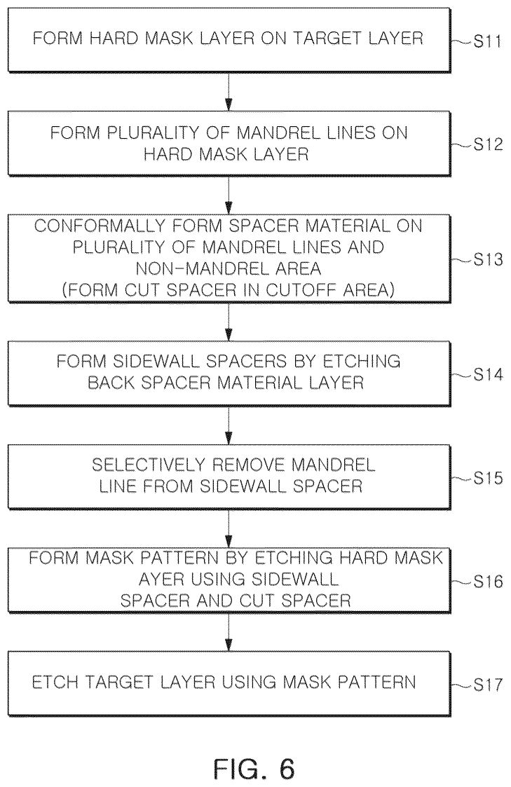

FIG. 6 is a flowchart illustrating a method of manufacturing a semiconductor device according to one or more embodiments.

First, in operation S11, a hard mask layer 130 is formed on the target layer (for example, dielectric layer 120). The target layer may be a layer to be etched (for example, a dielectric layer or a semiconductor layer) on which a fine pattern will be formed, and for example, may include a dielectric layer 120 to form an interconnection line such as a back end of line (BEOL). The hard mask layer 130 may have a required mask pattern through a subsequent self-aligned patterning process. For example, the hard mask layer 130 may include a first mark layer 131 and a second hard mask layer 132 sequentially stacked on the target layer. The first and second hard mask layers 131 and 132 may include different materials having etch selectivity in a subsequent etching process.

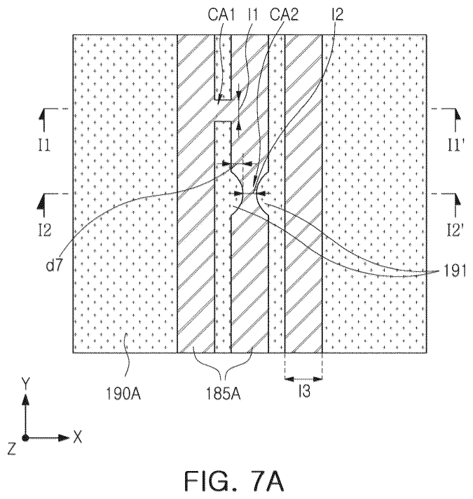

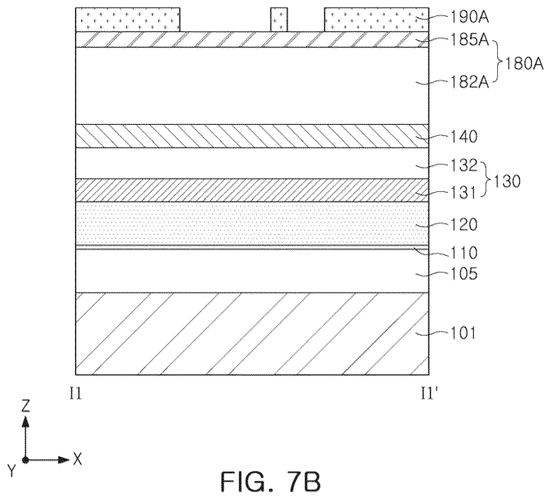

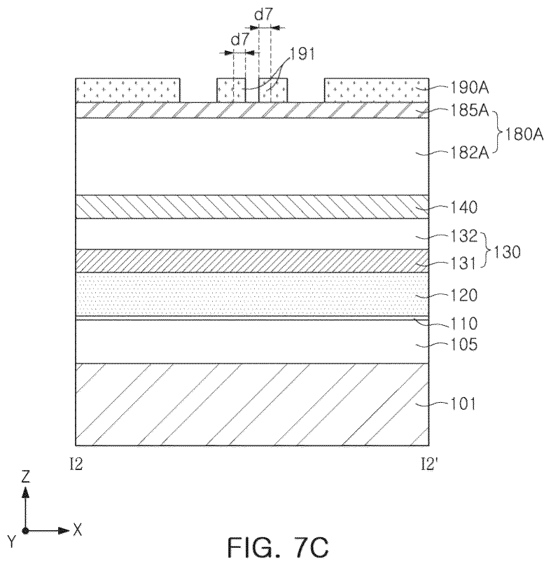

In operation S12, a plurality of mandrel lines 140L may be formed on the hard mask layer 130 (see FIGS. 7 to 9).

The mandrel layer 140 may be deposited on the hard mask layer 130 and the mandrel layer 140 may be patterned using a photolithography process to form a plurality of mandrel lines 140L. For example, mandrel layer 140 may include amorphous silicon. The plurality of mandrel lines 140L may be a structure having both sides extending in one direction. Each mandrel line 140L defines an area where a structure (for example, interconnection line) to be formed in a subsequent process will be formed. The area between the plurality of mandrel lines 140L may be defined as a non-mandrel area (NM). Among the non-mandrel areas NM, the area between sidewall spacers to be formed in a subsequent process may be used as an area where a pattern (for example, interconnection line) to be formed in a subsequent process is formed, similar to the mandrel line 140L.

Cut spacer regions CA1 and CA2 in which a portion of the mandrel line 140L is removed may also be formed. One mandrel line 140L extending in one direction may be separated into two or more sub-lines by these cut spacer regions CA1 and CA2. These cut spacer regions CA1 and CA2 may provide a space to separate patterns to be formed in a subsequent process. In the case of an interconnection line, two adjacent lines in the cut spacer regions CA1 and CA2 may be electrically insulated by the dielectric layer 120.

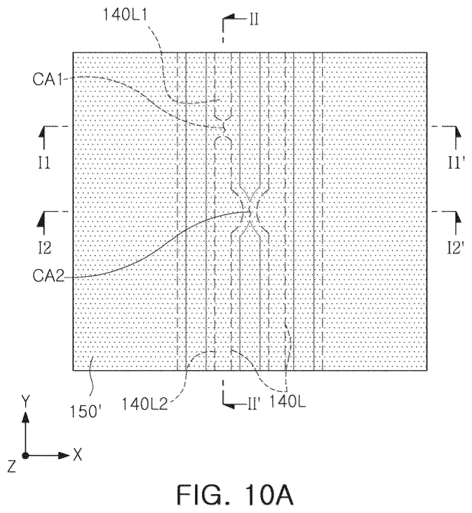

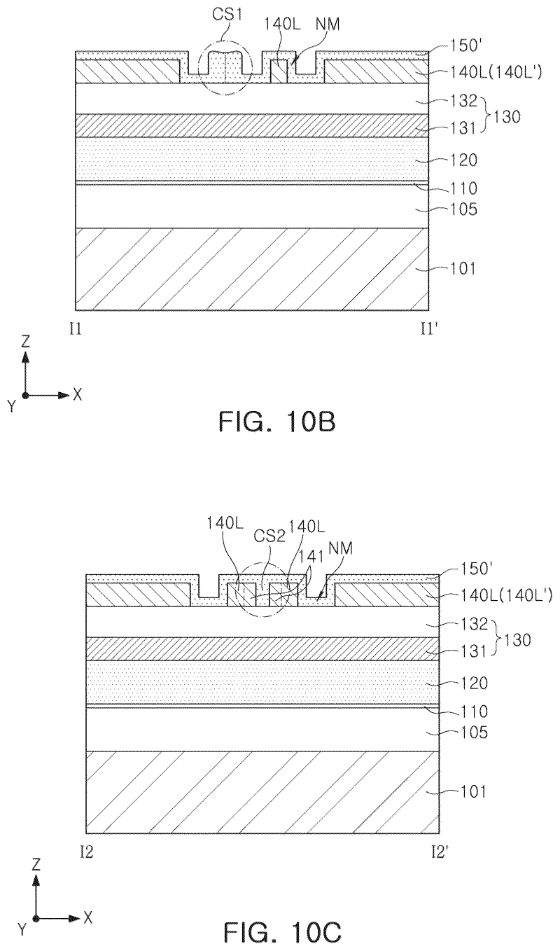

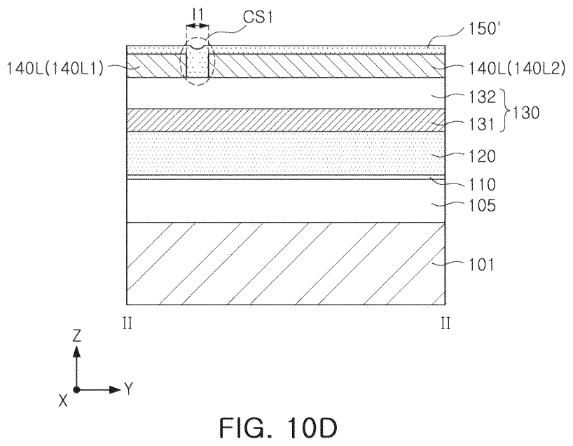

In operation S13, the spacer material layer 150′ may be conformally formed on the plurality of mandrel lines 140L and the non-mandrel area NM (see FIG. 10).

A spacer material layer 150′ may be formed on the surfaces of the plurality of mandrel lines 140L, for example, the top surface and both sides, and the non-mandrel area NM. For example, the spacer material layer 150′ may be conformally deposited using a process such as an atomic layer deposition (ALD) process. The spacer material layer 150′ may include, for example, silicon oxide, silicon nitride, titanium oxide, titanium nitride, or boron nitride. The thickness of the spacer material layer 150′ may be proportional to the pitch (or width) of the final pattern.

In operation S13, the previously formed cut spacer regions CA1 and CA2 are entirely filled with the spacer material layer 150′ to form cut spacers CS1 and CS2 (see FIG. 10).

In the mandrel line 140L, the separation distance of the cut spacer regions CA1 and CA2 satisfies the maximum separation distance (for example, about 20 nm) possible for photo processing, and is set to twice or less the thickness (approximately 11 nm) of the spacer material layer 150′ so that it may be filled with only the spacer material layer 150′. Therefore, the cut spacer regions CA1 and CA2 may be completely filled by the spacer material layer 150′. As a result, in the etch-back process, cut spacers CS1 and CS2 may be formed only by conformal coating of the spacer material layer without a separate pattern process or etching process for reinforcement.

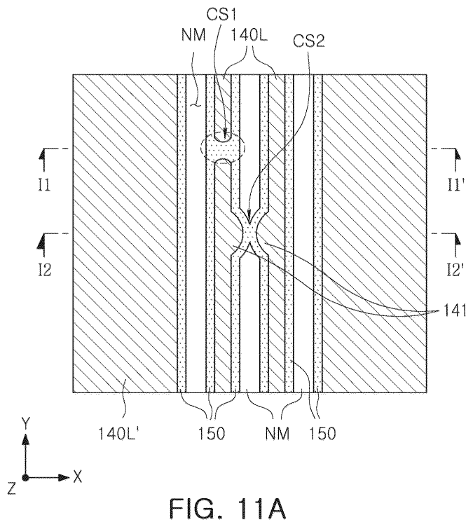

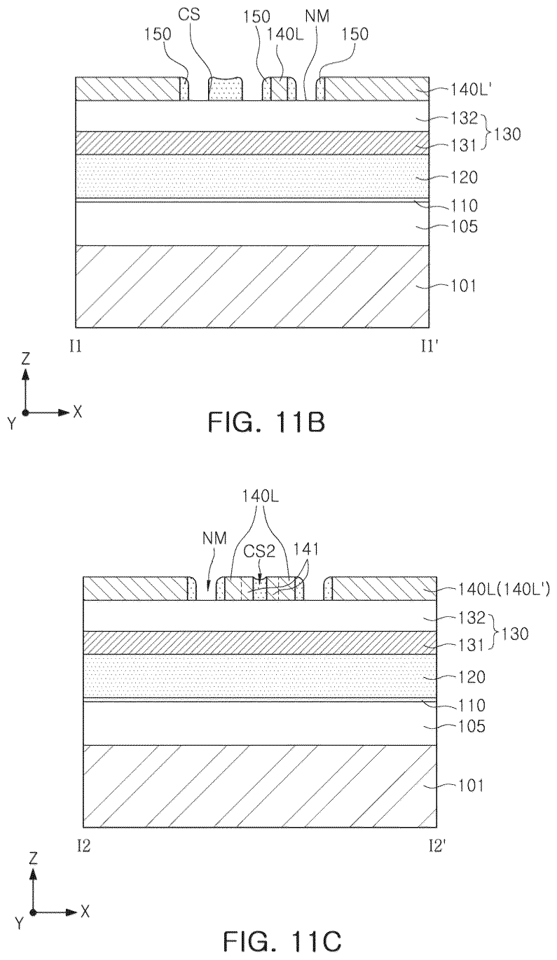

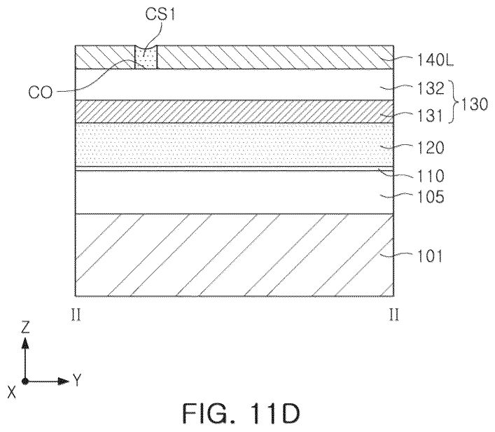

In operation S14, the spacer material layer 150′ is etched back to form sidewall spacers 150 on each sidewall of the plurality of mandrel lines 140L (see FIG. 11).

During the etching back process to form the sidewall spacer 150, the area excluding the cut spacer CS1 of the non-mandrel area (NM) between the sidewall spacers 150 on the hard mask layer 130 may be opened together with the upper surface of the plurality of mandrel lines 140L. This etch back process may be performed using an anisotropic RIE process.

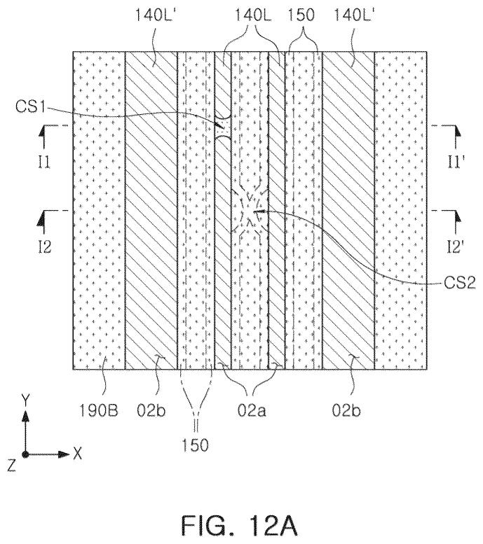

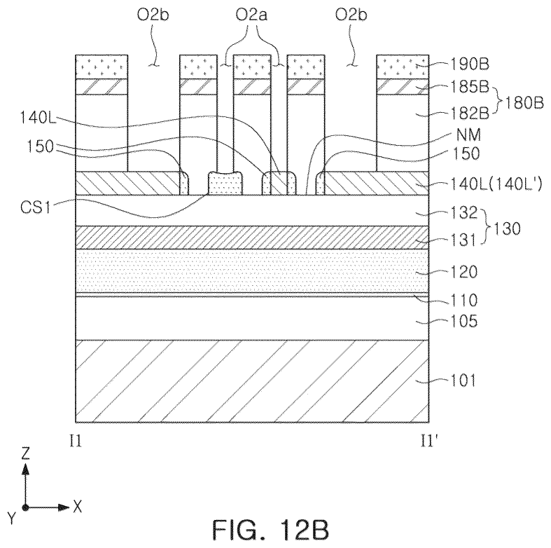

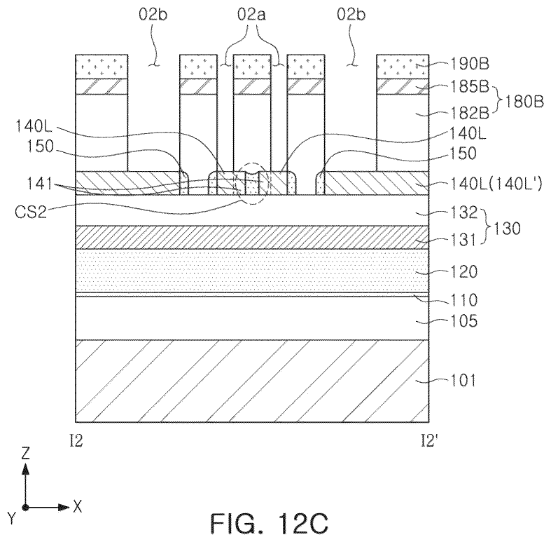

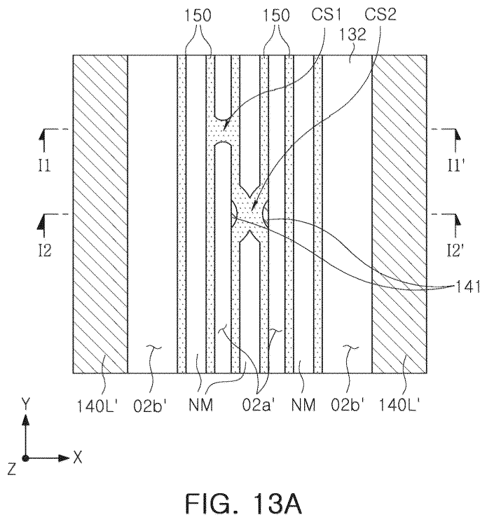

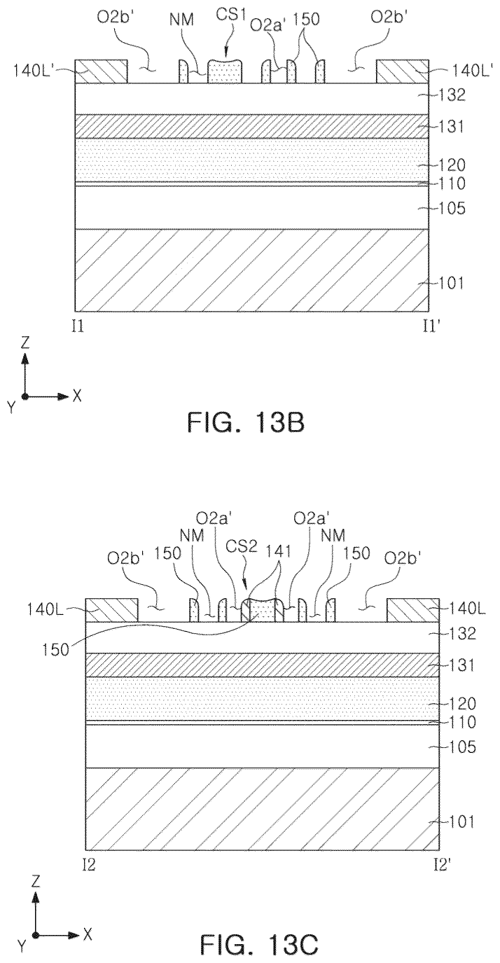

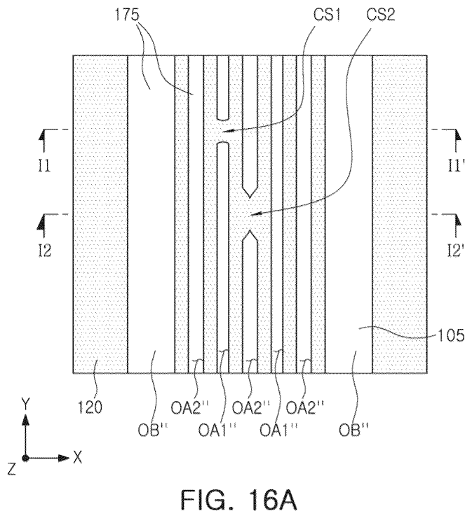

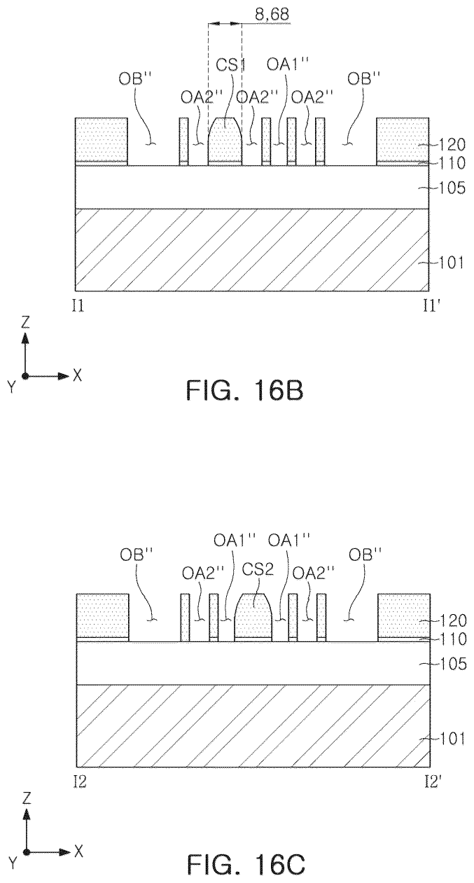

In operation S15, the mandrel line 140L is selectively removed from the sidewall spacer 150 (see FIG. 12), and in operation S16, a required mask pattern may be formed by etching the hard mask layer 130 using the sidewall spacer 150 and the cut spacers CS1 and CS2 (see FIGS. 13 to 15). In operation S17, the final pattern may be formed by etching the target layer using the mask pattern (see FIGS. 16 to 18).

In this case, the sidewall spacers 150 remaining on the sidewalls of each mandrel line 140L may be used as a structure that defines the spacing between the patterns. The area from which the mandrel line 140L is removed and the area between the sidewall spacers in the non-mandrel area NM may be provided as an area where the final pattern will be formed.

According to this embodiment, the cut spacer region CA1 of the mandrel line 140L is embedded with the spacer material layer 150′ without an internal gap, so that separate reinforcement photo process may be omitted. Additionally, the photo process for forming a cut-off in the cut spacer region CA2 of the non-mandrel area NM may be omitted. Accordingly, the cut spacer regions CA1 and CA2 are formed together while forming the mandrel line 140L, and by reflecting this when patterning the hard mask layer 130, an additional photo mask process for reinforcing a separate mask pattern may be omitted and a short circuit in the interconnection line may be formed in the required area.

Hereinafter, the method of manufacturing a semiconductor device according to one or more embodiments will be described in more detail with reference to FIGS. 7 to 18.

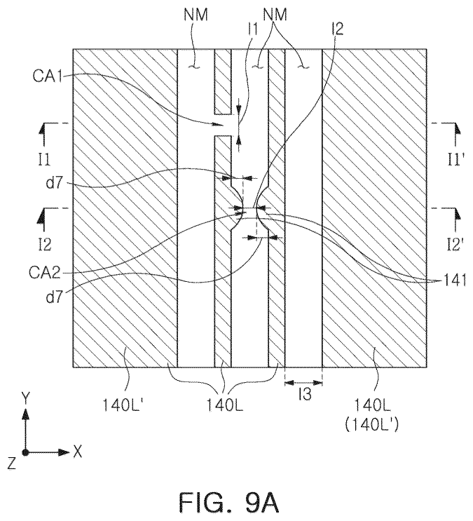

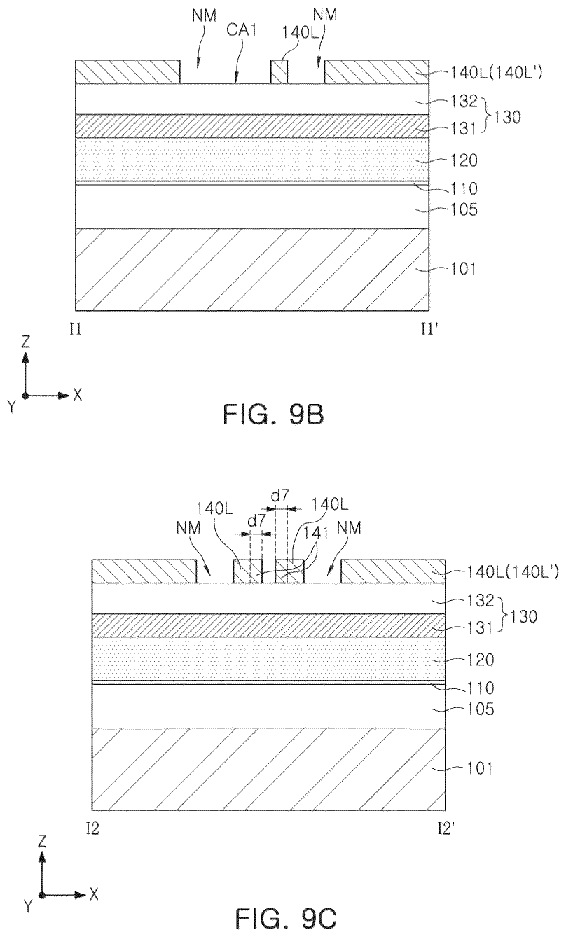

FIGS. 7A and 9A are top plan views illustrating the mandrel line forming process in the method of manufacturing a semiconductor device according to one or more embodiments, FIGS. 7B and 9B are cross-sectional views taken along line I1-I1′ of the plane of FIGS. 7A and 9A, respectively, and FIGS. 7C and 9C are cross-sectional views of the plane of FIGS. 7A and 9A taken along line I2-I2′, respectively.

Referring to FIGS. 7A to 7C, a substrate 101 on which an interlayer insulating layer 105 is disposed is illustrated. A dielectric layer 120 to form an interconnection structure is formed on the interlayer insulating layer 105, and a hard mask layer 130, a mandrel layer 140, and a first mask stack 180A are sequentially stacked on the dielectric layer 120. The first mask stack 180A is a mask structure for patterning the mandrel layer 140, and a first photoresist pattern 190A is formed on the first mask stack 180A.

This process illustrates a process for forming a mandrel line (“140L” in FIGS. 9A to 9C) using a photolithography process. After coating (for example, spin coating) a photoresist material on the first mask structure 180A, a first photoresist pattern 190A is formed through baking, exposure, and development processes. The first photoresist pattern 190A may use a positive tone resist having a positive tone development process, or may use a negative tone development (NTD) process using a solvent-based developer. Exposure to form the first photoresist pattern 190A may be performed by, for example, extreme ultraviolet (EUV) (for example, 13.5 nm), but embodiments are not limited thereto. Other exposure facilities such as ArF excimer laser (193 nm) may be used. The first photoresist pattern 190A is patterned with an image corresponding to the required mandrel line (“140L” in FIGS. 4A and 4B), and the first mask structure 180A may be patterned using the first photoresist pattern 190A.

The first photoresist pattern 190A may include an open area so that the lower first mask stack 180A may be etched and patterned.

The area covered by the first photoresist pattern 190A is the mandrel area where the remaining mandrel line 140L is formed in the mandrel layer 140, and the open area may be a non-mandrel area (NM).

The first photoresist pattern 190A may open the first cut spacer region CA1 corresponding to the first cut spacer CS1 formed in the mandrel area. In addition, for the second cut spacer region CA2 corresponding to the second cut spacer CS2 formed in the non-mandrel area (NM), an enlarged portion 191 of the mandrel line 140L may be included to reduce the opening width.

The first cut spacer region CA1 is for forming a short circuit of the mandrel layer (140) for the first cut spacer CS1 of the mandrel area, and may be formed to have a first separation distance I1 in the Y-direction between the first photoresist patterns 190A.

The first separation distance I1 may have a size that is twice or less the thickness of the conformal coating layer of the spacer material layer 150′, to be filled by the spacer material layer 150′ surrounding the mandrel layer 140. Accordingly, all of the first cut spacer region CA1 corresponding to the first separation distance I1 may be filled with the spacer material layer 150′ by conformal coating for the sidewall spacer formed later.

The second cut spacer region CA2 is an area that partially extends toward the open area between the two continuous first photoresist patterns 190A in the Y-direction to reduce the gap between the open areas, and enlarged portions 191 protruding from both sides may be formed so that the first separation width I3 in the X-direction of the open area constituting the non-mandrel area MN is reduced to the second separation width I2 in the X-direction.

In this case, the shape of the protruding enlarged portion 191 may have a curvature to have the largest protrusion length from the center as illustrated in FIG. 7A, and may be a semicircle or oval. Alternatively, the shape of the protruding enlarged portion 191 may have a quadrangular shape, and in the case of this shape, a third interconnection line including the fifth side surface Se as illustrated in FIG. 4 may be formed.

The second separation width I2 may have a size that is twice or less the thickness of the spacer material layer 150′ formed later, and accordingly, the entirety of the second cut spacer region CA2 corresponding to the second separation width I2 may be filled with the spacer material layer 150′ by conformal coating for the sidewall spacer formed later.

For example, in the EUV photo process, reliable photo mask etching may be performed only when the separation distance between interconnections is secured to 20 nm or more. Accordingly, the second separation width I2 may be reduced only to 20 nm. Therefore, when the first separation width I3 is about 26 nm, the maximum protrusion length d7 of the enlarged portion 191 may be set to 3 nm, and may be patterned to enable short-circuiting of interconnection at a required location. At this time, when the conformal coating thickness of the spacer material layer 150′ satisfies about 11 nm, since a second separation width I2 of 22 nm or less, which is twice as large, is obtained, the second cut spacer region CA2 may be sufficiently gap-filled by the spacer material layer 150′ later.

In this case, the shape of the enlarged portion 191 for the second cut spacer CS2 is formed to have a semicircle or oval, so that a disconnection distance equal to the overlapping length of the two enlarged portions 191 may be secured.

Therefore, a continuous interconnection line may be disconnected without adding a separate etching process, and the disconnection distance may be secured.

The substrate 101 may be a semiconductor substrate or a multilayer substrate such as Silicon On Insulator (SOI).

The dielectric layer 120 may be provided as an area for forming an interconnection line such as BEOL, and the dielectric layer 120 may be formed on the interlayer insulating layer 105 with the etch stop film 110 interposed therebetween.

The hard mask layer 130 employed in this embodiment may include first and second hard mask layers 131 and 132 sequentially stacked on the dielectric layer 120. The first and second hard mask layers 131 and 132 may include different materials having etch selectivity in a subsequent etching process. For example, the first hard mask layer 131 may include a metal compound such as titanium nitride suitable for a hard mask. The second hard mask layer 132 may include a dielectric material such as silicon oxide, silicon oxynitride, or silicon nitride.

The mandrel layer 140 may include a material having a high etch selectivity with respect to the second hard mask layer 132 located below. For example, mandrel layer 140 may include amorphous silicon. For example, the first and second hard mask layers 131 and 132 and the mandrel layer 140 may be formed by various deposition processes such as physical vapor deposition (PVD), chemical vapor deposition (CVD), and atomic layer deposition (ALD).

The first mask structure 180A may include a first hard mask layer 182A and a first anti-reflection layer 185A sequentially formed on the mandrel layer 140. For example, the first hard mask layer 182A may include a carbon-containing layer such as spin on hardmask (SOH), silicon oxide, silicon nitride, or silicon nitride, and similar to the hard mask layer 130, may be composed of two layers made of different materials. For example, the first anti-reflection layer 185A may include titanium, titanium dioxide, titanium nitride, chromium oxide, carbon, silicon nitride, silicon oxynitride, and amorphous silicon.

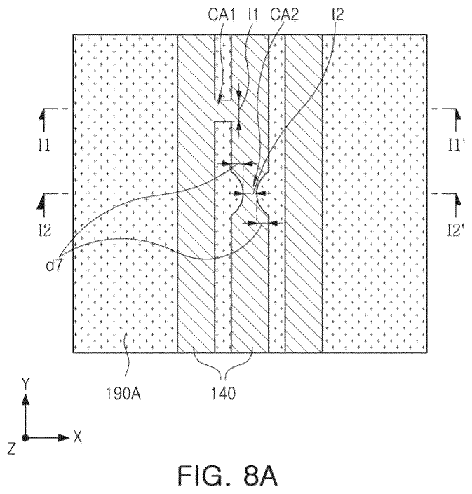

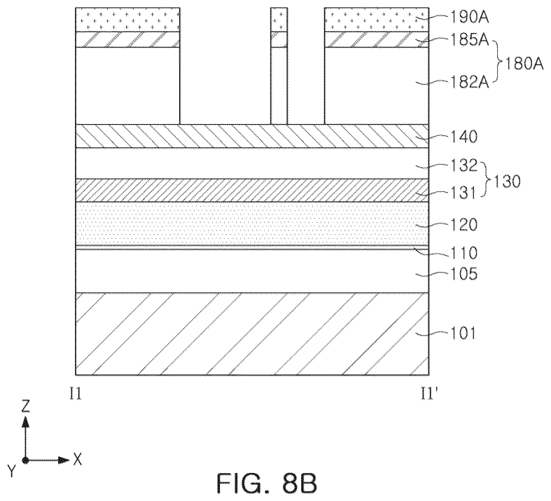

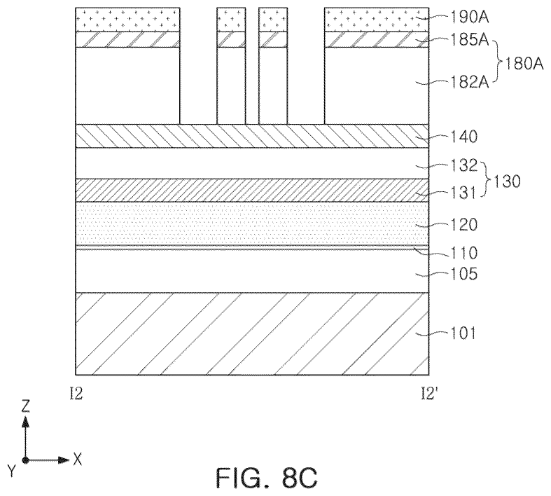

Referring to FIGS. 8A to 8C, the first mask stack 180A is patterned using the first photoresist pattern 190A, and next, referring to FIGS. 9A to 9C, a plurality of mandrel lines 140L are formed from the mandrel layer 140 using the first mask stack 180A, and the first mask stack 180A is removed.

First, the first photoresist pattern 190A is transferred to the first mask stack 180A to form a pattern for a plurality of mandrel lines 140L, and the mandrel layer 140 may be patterned using the patterned first mask stack 180A to form a plurality of mandrel lines 140L. For example, this etching process may be performed by an anisotropic process such as reactive ion etching (RIE).

The plurality of mandrel lines 140L extend in the Y-direction and may be arranged to be spaced apart in the X-direction intersecting the Y-direction. Additionally, the plurality of mandrel lines 140L may have side walls extending in the Y-direction. In this embodiment, the plurality of mandrel lines 140L may include a peripheral mandrel area 140L′ constituting a peripheral circuit in addition to the mandrel lines defining the interconnection lines. The interconnection lines (Ma, Mb in FIG. 1) that are included in the peripheral circuit may have a relatively large size, and thus may not be formed by the self-aligned patterning process according to this embodiment, but may be formed by a general photo lithography process.

In addition, the surface of the hard mask layer 130 is exposed between the plurality of mandrel lines 140L (first opening), and the exposed area between the plurality of mandrel lines 140L may be defined as a non-mandrel area (NM). The non-mandrel area (NM) may also include an area where an interconnection line will be formed.

Some of these mandrel lines 140L include a first cut spacer region CA1 for the first cut spacer CS1, and an enlarged portion 141 for the second cut spacer region CA2 may be disposed in the non-mandrel area NM.

At this time, the first cut spacer region CA1 may have a width equal or substantially equal to the separation distance I1 of the first photo mask pattern 190A described above, and may have a size that is twice or less the thickness of the spacer material layer 150′.

In addition, expansion portions 141 of the mandrel lines 140L on both sides are formed, and the second cut spacer region CA2 of the non-mandrel area (NM) has a second separation width I2 smaller than the first separation width I3 of the non-mandrel area (NM), and the second spacing width I2 of the expansion portion 141 in the X-direction may also satisfy twice or less the thickness of the spacer material layer 150′.

In addition, the expansion portion 141 of the mandrel line 140L on both sides may have a maximum protrusion length d7 sufficient to secure the minimum separation distance of 20 nm for the photo process with respect to the first separation width I3 as described previously. For example, when the first separation width I3 is 26 nm and the minimum separation distance of the photo process is 20 nm, a maximum protrusion length d7 of 3 nm, which is half the difference between the two values, may be obtained.

Therefore, the maximum protrusion length d7 of the enlarged portion 141 may be set such that the second separation width I2 is smaller than 22 nm, which is twice 11 nm that is the thickness of the spacer material layer 150′, and satisfies the maximum separation length (about 20 nm) of the photo process.

As illustrated in FIGS. 10A to 11D, a process of forming the sidewall spacer 150 from the spacer material layer 150′ is performed.

FIGS. 10A and 11A are top plan views illustrating the formation of sidewall spacers in the method of manufacturing a semiconductor device according to one or more embodiments, FIGS. 10B and 11B are cross-sectional views taken along line I1-I1′ on the plane of FIGS. 10A and 11A, respectively, FIGS. 10C and 11C are cross-sectional views taken along line I2-I2′ of the plane of FIGS. 10A and 11A, respectively, and FIGS. 10D and 11D are cross-sectional views taken along line II-II′ of the plane of FIGS. 10A to 11a, respectively.

Referring to FIGS. 10A to 10D, a spacer material layer 150′ may be conformally formed on the hard mask layer 130 on which the mandrel line 140L is disposed.

A spacer material layer 150′ for the sidewall spacer 150 may be formed on the second hard mask layer 103 to cover the top and side surfaces of the plurality of mandrel lines 201. For example, the spacer material layer 150′ may be conformally deposited using a process such as an ALD process. The spacer material layer 150′ may provide sidewall spacers (also referred to as self-aligned patterns) through a subsequent process. The spacer material layer 150′ may include, for example, silicon oxide, silicon nitride, titanium oxide, titanium nitride, or boron nitride.

The thickness of the spacer material layer 150′ may be proportional to the width of the sidewall spacer (150 in FIGS. 10B and 110D), for example, the spacing of the final pattern. Accordingly, the spacer material layer 150′ tends to become thinner in order to implement a fine pitch pattern. For example, the thickness of the spacer material layer 150′ may be 15 nm or less, preferably, approximately 11 nm.

At this time, the spacer material layer 150′ may be filled in the first cut spacer region CA1 formed in the previous process to form a first cut spacer CS1. For stable separation, the first cut spacer CS1 is completely filled in the first cut spacer region CA1, and since the separation width I1 of the first cut spacer region CA1 is twice or less the width of the spacer material layer 150′, sufficient filling is possible.

In addition, a spacer material layer 150′ is coated along the extended surface of the non-mandrel area NM by the extended portion 141. A spacer material layer 150′ is coated along the side of the expansion portion 141 to fill the second spacing width I2. Therefore, the spacer material layer 150′ on both sides of the expansion portion 141 is coated, thereby filling the second cut spacer region CA2 without a space. No additional photoprocess or filling process is required.

The second separation width I2 may be set to be smaller than twice the thickness of the spacer material layer 150′, so that the second cut spacer region CA2 is completely filled by the spacer material layer 150′ without a separate separation space.

Accordingly, the non-mandrel area NM with the second cut spacer CS2 may be separated into two completely separate open areas by the filled spacer material layer 150′.

Next, referring to FIGS. 11A to 11D, the sidewall spacer 150 may be formed by applying etch-back to the spacer material layer 150′.

The spacer material layer 150′ is etched back to form sidewall spacers 150 on each sidewall 140S of the plurality of mandrel lines 140L. In this etching back process, the upper surface of the plurality of mandrel lines 140L is opened, and the spacer material layer portion located on the side wall 140S of the plurality of mandrel lines 140L remains as the sidewall spacer 150, and the remaining sidewall spacers 150 may define the spacing of the final pattern. The sidewall spacer 150 is also referred to as a “self-aligned pattern.” In addition, the area excluding the second cut spacer CS2 among the non-mandrel areas (NM) between the sidewall spacers 150 on the second hard mask layer 132 may be opened together with the upper surface of the plurality of mandrel lines 140L. For example, etch back to form the sidewall spacer 150 may be performed using an anisotropic RIE process.

Additionally, the spacer material layer 150′ may remain in the first cut spacer CS1 to form the first cut spacer CS1. The first cut spacer CS1 and the second cut spacer CS2 are formed only of the spacer material layer 150′, so their upper surfaces may have a concave shape to a predetermined depth. This may be negligible, for example, similar to some degree of inclination of the sidewall spacer 150.

Referring to FIGS. 12A to 12C, a second mask stack 180B is formed on the hard mask layer 130 where the mandrel line 140 and the sidewall spacer 150 are located, and second and second openings O2a and O2b that open the area corresponding to the mandrel line 140L are formed on the second mask stack 180B using the second photoresist pattern 190B.

A second hard mask layer 182B and a second anti-reflection layer 185B are sequentially formed as a second mask stack 180B on the hard mask layer 130, and second and third openings O2a and O2b may be formed in the second mask structure 180B using the second photoresist pattern 190B. The process using the second mask stack 180B and the second photoresist pattern 190B may be incorporated with the description of the photo lithography process described above by reference, except that it has a pattern shape, for example, second and third openings O2a and O2b.

The second and third openings O2a and O2b may be designed to remove the mandrel line 140L in contact with the sidewall spacer 150. The second opening O2a is formed in an area where the sidewall spacer 150 corresponds to the mandrel line 140L located on both side walls, and the third opening O2b may be configured to remove a relatively large area from the peripheral mandrel area 140L′. In some embodiments, the area obtained by the third opening O2b may be provided as a space for forming a peripheral circuit.

Referring to FIGS. 13A to 13C, a self-aligned pattern composed of sidewall spacers 150 may be obtained by selectively removing the mandrel line 140L using the second mask stack 180B. Next, the second mask stack 180B may be removed.

The sidewall spacers 150, which are self-aligned patterns, define the spacing of the final pattern, and the line spaces O2a′ and NM′ between the sidewall spacers 150 may define the width of the final pattern. As illustrated in FIG. 13A, the first line space O2a′ from which the mandrel line 140L is removed and the second line space NM′ defined in the non-mandrel area may define an area for a fine pattern. In this case, as illustrated in FIGS. 13A and 13B, the first line space O2a′ on the left may be stably divided into two line spaces by the first cut spacer CS1. The first cut spacer CS1 may be completely filled only with the spacer material layer 150′. Additionally, the second line space NM′ on the left may be stably divided into two line spaces by the second cut spacer CS2. In particular, the second cut spacer CS2 may be formed with a spacer material layer 150′ remaining in the central area and enlarged portions 141 extending from the mandrel line 140L on both sides thereof. Accordingly, the side of the second cut spacer CS2 may be formed to have two parallel sides in the Y-direction like other line spaces.

On the other hand, the line space O2b′ located in the peripheral mandrel area 140L′ has a relatively large width. For example, an interconnection line constituting a peripheral circuit may be formed in this line space O2b′.

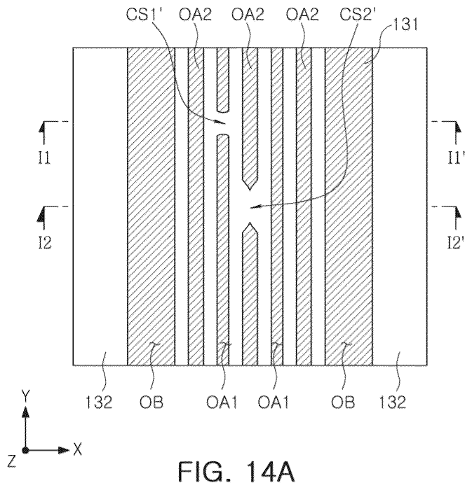

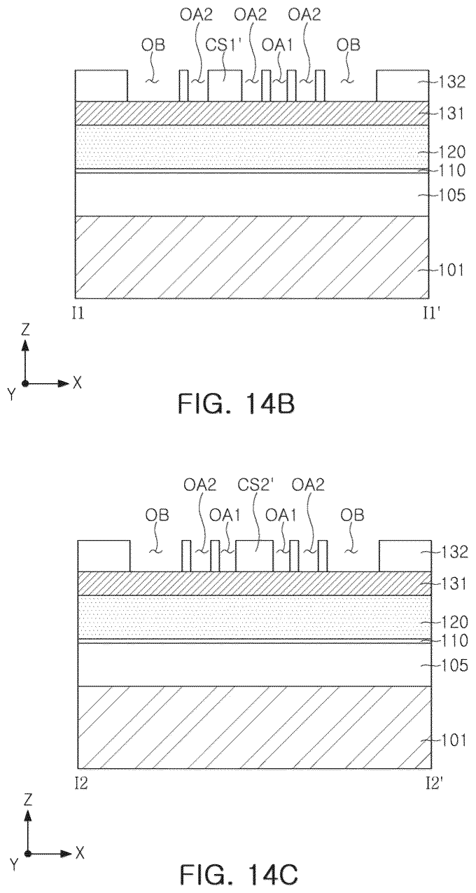

Referring to FIGS. 14A to 14C, a second mask pattern is formed by etching the second hard mask layer 132 using the first and second cut spacers CS1 and CS2 along with the sidewall spacers 150.

In the second mask pattern, two first line spaces (OA1) and two second line spaces (OA2) are alternately arranged, and the first and second line spaces (OA1, OA2) located on the left may be separated into two line spaces by patterns (CS1′, CS2′) formed by the first and second cut spacers CS1 and CS2, respectively. Additionally, both sides may have a third line space OB defined by the line space O2b′ of the peripheral mandrel area 140L′.

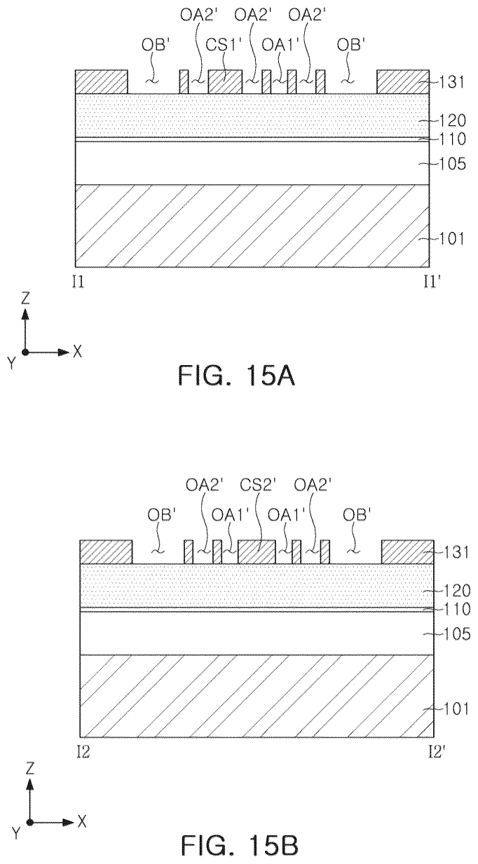

Referring to FIGS. 15A and 15B, the first mask pattern may be formed by etching the first hard mask layer 132 using the second mask pattern.

Similar to the second mask pattern, even in the first mask pattern, first to third line spaces OA1′, OA2′, and OB′ may be provided in areas corresponding to the first to third line spaces OA1, OA2, and OB. The first and second line spaces (OA1′, OA2′) located on the left may also be divided into two line spaces by patterns (CS1′, CS2′) defining the first and second cut spacers CS1 and CS2, respectively.

FIGS. 16A to 18B are plan and cross-sectional views respectively illustrating the interconnection line forming process of the method of manufacturing a semiconductor device according to one or more embodiments.

Referring to FIGS. 16A and 16C, the dielectric layer 120, which is the target layer, is patterned using the first mask pattern. First to third trenches OA1″, OA2″, and OB″ respectively corresponding to the first to third line spaces OA1′, OA2′, and OB′ are formed in the dielectric layer 120. In this process, portions of the etch stop film 110 exposed on the bottom surfaces of the first to third trenches OA1″, OA2″, and OB″ may also be removed. The first to third trenches OA1″, OA2″, and OB″ may define the shape of an interconnection line to be formed in a subsequent process. The first and second trenches OA1″ and OA2″ located on the left may also be divided into two regions by the first and second cut spacers CS1 and CS2.

At this time, the dielectric layer 120 defining the first and second cut spacers CS1 and CS2, respectively, has a larger width than the other dielectric layers 120. Because the space in which the etchant flows is narrow, overetching may occur in some areas, resulting in a curved surface at the edge of the upper surface.

Accordingly, as illustrated in FIGS. 16B and 16C, the edges of the first and second cut spacers CS1 and CS2 may be worn at the edge areas of the upper surfaces, so that the width of the upper surface may be reduced than the width of the lower surface.

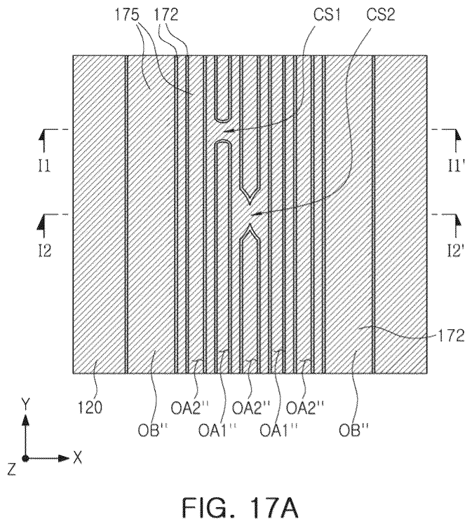

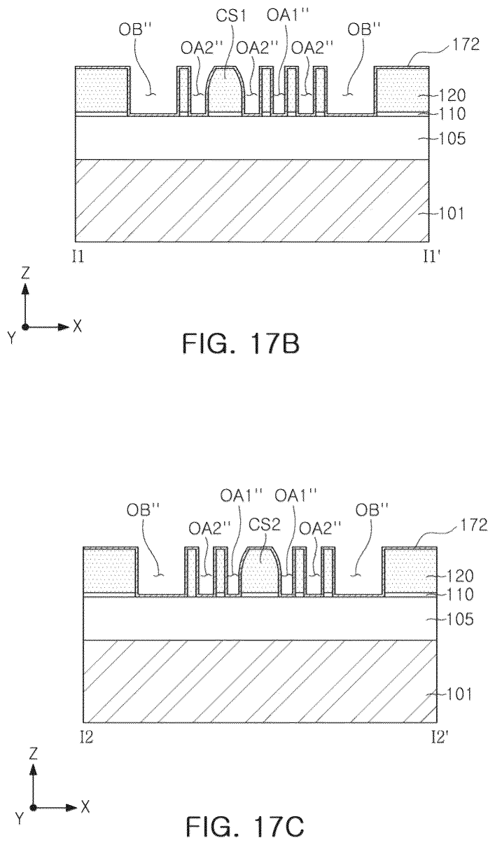

Referring to FIGS. 17A to 17C, a conductive barrier 172 may be formed on the dielectric layer 120 in which the first to third trenches OA1″, OA2″, and OB″ are formed. The conductive barrier 172 may be employed to prevent elements in the metal layer to be formed in a subsequent process from diffusing. For example, the conductive barrier 172 may include a conductive nitride such as titanium nitride (TiN), tantalum nitride (TaN), aluminum nitride (AlN), or tungsten nitride (WN).

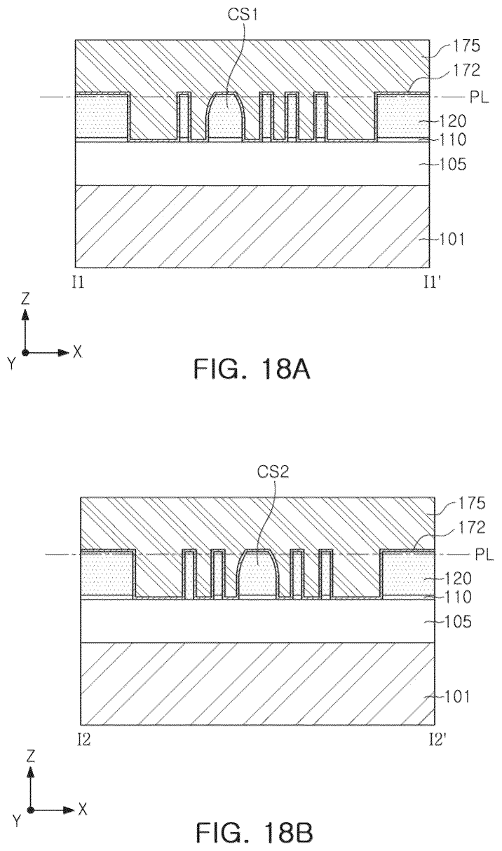

Referring to FIGS. 18A and 18B, a metal layer 175 is formed on the dielectric layer 120 to fill the first to third trenches OA1″, OA2″, and OB″. The metal layer 175 may include, for example, gold (Au), titanium (Ti), copper (Cu), silver (Ag), aluminum (Al), tungsten (W), cobalt (Co), chromium (Cr), molybdenum (Mo), and zirconium. (Zr), nickel (Ni), tantalum (Ta), platinum (Pt) or alloys thereof. The metal layer may be formed, for example, by a deposition process such as physical vapor deposition (PVD), chemical vapor deposition (CVD), and a plating process such as electroplating and electroless plating.

Next, a planarization process of the metal layer 175 may be performed. The planarization process of the metal layer 175 may be performed until the top surface of the dielectric layer 120 is exposed (“PL” line). This planarization process may be performed, for example, by a chemical mechanical polishing (CMP) process.

As a result, as illustrated in FIG. 1, the first to fifth interconnection lines M1, M2, M3, M4 and M5 and two peripheral interconnection lines Ma and Mb may be formed in the dielectric layer 120. The second interconnection line M2 is separated into two interconnection lines (M2a and M2b) by the first cut spacer CS1, and similarly, the third interconnection line M3 may be separated into two interconnection lines M3a and M3b by the second cut spacer CS2. The first and second cut spacers CS1 and CS2 may be formed to have a shape that satisfies the shape of the first and second cut spacers CS1 and CS2, without additional reinforcement of genetic material, when forming sidewall spacers for self-aligned patterning.

As set forth above, according to one or more embodiments, by including a shape for separating lines in a mask pattern forming a mandrel line, filling and etching processes of an additional spacer dielectric material may be omitted in subsequent processes. Therefore, the number of masks may be significantly reduced, and thus the process may be simplified. Additionally, by changing the shape of an initial mask pattern, short circuit problems between metal lines to be formed in a subsequent process may be reliably prevented. In this manner, a self-aligned pattern including regions in which lines are separated by simplification of the number of masks and the etching process may be formed.

While embodiments have been illustrated and described above, it will be apparent to those skilled in the art that modifications and variations could be made without departing from the scope of the present inventive concept as defined by the appended claims and their equivalents.

What is claimed is:

1. A semiconductor device comprising:
a lower structure;
a dielectric layer on the lower structure; and
first interconnection lines and second interconnection lines extending in a first direction in the dielectric layer and alternately disposed and spaced apart from each other in a second direction, perpendicular to the first direction,
wherein at least one of the first interconnection lines comprises a first subpattern and a second subpattern overlapping in the first direction and spaced apart from each other,
wherein at least one of the second interconnection lines comprises a third subpattern and a fourth subpattern overlapping in the first direction and spaced apart from each other,
wherein two ends of the first subpattern and the second subpattern facing each other in the first direction have a convex protruding shape, and
wherein two ends of the third subpattern and the fourth subpattern facing each other in the first direction have a concave protruding shape.

2. The semiconductor device of claim 1, further comprising:
a first cut spacer comprising the dielectric layer between the first subpattern and the second subpattern; and
a second cut spacer comprising the dielectric layer between the third subpattern and the fourth subpattern.

3. The semiconductor device of claim 2, wherein the first cut spacer and the second cut spacer have different shapes.

4. The semiconductor device of claim 1, wherein a separation distance between the third subpattern and the fourth subpattern decreases toward a center line of a width of the third subpattern and the fourth subpattern.

5. The semiconductor device of claim 4, wherein the two ends of the third subpattern and the fourth subpattern comprise:
a first side surface and a second side surface parallel to the center line of the width,
a third side surface that is curved and extending from the first side surface, and
a fourth side surface that is curved and extending from the second side surface to the third side surface,
wherein an intersection point of the third side surface and the fourth side surface forms an edge point.

6. The semiconductor device of claim 5, wherein the third side surface and the fourth side surface have a concave curved surface toward the center line of the width.

7. The semiconductor device of claim 5, wherein, based on the center line of the width of the third subpattern coinciding with the center line of the width of the fourth subpattern, the separation distance between the third subpattern and the fourth subpattern is minimum between the edge point of the third subpattern and the edge point of the fourth subpattern.

8. The semiconductor device of claim 5, wherein the two ends of the first subpattern and the second subpattern, respectively comprises:
a first side surface and a second side surface parallel to a center line of awidth of the first subpattern and the second subpattern,
a third side surface that is curved and extending from the first side surface, and
a fourth side surface that is curved and extending from the second side surface to the third side surface,
wherein an intersection point of the third side surface and the fourth side surface forms an inflection point.

9. The semiconductor device of claim 8, wherein the third side surface and the fourth side surface have a convex curved surface toward the center line of the width.

10. The semiconductor device of claim 9, wherein a distance between the inflection point of the first subpattern and the inflection point of the second subpattern is smaller than a distance between the edge point of the third subpattern and the edge point of the fourth subpattern.

11. The semiconductor device of claim 1, wherein a separation distance between the first subpattern and the second subpattern is less than twice a separation distance between the first interconnection lines and the second interconnection lines.

12. The semiconductor device of claim 2, further comprising:
first protrusions protruding from adjacent second interconnection lines on two sides of the first cut spacer and on the dielectric layer of the first cut spacer; and
second protrusions protruding from adjacent first interconnection lines on two sides of the second cut spacer and on the dielectric layer of the second cut spacer.

13. The semiconductor device of claim 12, wherein the first protrusions and the second protrusions have different shapes.

14. The semiconductor device of claim 13, wherein the second protrusions have a shape protruding convexly toward a center of the second cut spacer.

15. A semiconductor device comprising:
a lower structure;
a plurality of spacers extending in a first direction on the lower structure and spaced apart in a second direction perpendicular to the first direction;
first subpatterns and second subpatterns, overlapping in the first direction between the plurality of spacers, on the lower structure, the first subpatterns and second subpatterns having two ends opposite to each other being spaced apart from each other and protruding convexly;
third subpatterns and fourth subpatterns spaced apart from the first subpatterns and the second subpatterns in the second direction, between the plurality of spacers, on the lower structure, and overlapping in the first direction, the third subpatterns and the fourth subpatterns having two ends opposite to each other being spaced apart from each other and protruding concavely;
a first cut spacer between the first subpattern and the second subpattern, a material of the first cut spacer being same as a material of the plurality of spacers; and
a second cut spacer between the third subpattern and the fourth subpattern, a material of the second cut spacer being same as the material of the plurality of spacers,
wherein a minimum separation distance between the first subpattern and the second subpattern is less than a minimum separation distance between the third subpattern and the fourth subpattern.

16. The semiconductor device of claim 15, wherein the minimum separation distance between the first subpattern and the second subpattern is less than twice a width of the plurality of spacers.

17. The semiconductor device of claim 15, further comprising:
first protrusions on a portion of an upper surface of the first cut spacer and on sides of the first cut spacer; and
second protrusions on a portion of an upper surface of the second cut spacer and on sides of the second cut spacer,
wherein an upper surface of the first protrusions and an upper surface of the second protrusions are coplanar with the upper surface of the first cut spacer and the upper surface of the second cut spacer.

18. A method of manufacturing a semiconductor device, comprising:
forming a hard mask layer on a target layer;
forming, on the hard mask layer, a plurality of mandrel lines respectively comprising side walls extending in a first direction and spaced apart in a second direction intersecting the first direction, based on a first mask, and each of the plurality of mandrel lines comprising a first cut spacer region disconnected in the first direction and a second cut spacer region divided by enlarged portions having a width increasing in the first direction;
forming a first cut spacer in the first cut spacer region and forming a second cut spacer between the enlarged portions of the second cut spacer region by conformally forming a spacer material layer on the plurality of mandrel lines and filling the first cut spacer region and the second cut spacer region;
forming sidewall spacers on the sidewalls of the plurality of mandrel lines respectively by etching back the spacer material layer;
removing the plurality of mandrel lines from the sidewall spacers and the enlarged portions based on a second mask;
forming a mask pattern by etching the hard mask layer using the first cut spacer and the second cut spacer along with the sidewall spacers;
forming a plurality of trenches by etching the target layer based on the mask pattern; and
forming a plurality of interconnection lines by filling the plurality of trenches with a conductive material.

19. The method of claim 18, wherein a width of the first cut spacer region in the first direction is less than twice a thickness of the spacer material layer in a third direction perpendicular to the first direction and the second direction, and
wherein a separation distance between the enlarged portions of the second cut spacer region in the second direction is less than twice the thickness of the spacer material layer in the third direction.

20. The method of claim 18, wherein the forming the second cut spacer comprises dividing a non-mandrel area between the mandrel lines into a first opening area and a second opening area overlapping in the first direction, and
wherein the first opening area and the second opening area have shapes protruding concavely from each other.
